(19) United States
(12) Patent Application Publication
(10) Pub. No.: US 2009/0316056 A1
(43) Pub. Date: Dec. 24, 2009

(54) DIGITAL PICTURE FRAME DEVICE AND SYSTEM

(76) Inventors: Allan Rosencwaig, Danville, CA (US); Li Chen, Fremont, CA (US)

Correspondence Address: DLA PIPER LLP (US ), 2000 UNIVERSITY AVENUE, EAST PALO ALTO, CA, 94303-2248, US

(21) Appl. No.: 12/142,386

(22) Filed: Jun. 19, 2008

(51) Int. Cl. H04N 5/64; H05K 11/00; H04B 1/38; G06F 17/00

(52) U.S. Cl. 348/836; 455/344; 455/73; 700/94; 348/E05.128

(57) ABSTRACT

A digital picture frame device and system for displaying digital content. The digital picture frame device includes a display screen, a frame surrounding a periphery of the display screen, a compartment accessible by an opening in a side surface of the frame, a movable door for selectively covering the opening, a memory device port disposed in the compartment for receiving a memory device containing digital content, and control circuitry for controlling a display of the digital content on the display screen. A computer with a processor and a computer-readable medium having computer-executable instructions thereon can generate or receive digital content and associate at least some of the digital content with one or more playlists. A communications link transfers the playlists of the digital content to the picture frame for display on the display screen. Multiple inputs can be used for receiving and displaying different kinds of digital content.

### FIELD OF THE INVENTION

The present invention relates to consumer electronic devices commonly referred to as digital picture frames.

### BACKGROUND OF THE INVENTION

Currently, several manufacturers offer a consumer electronic device commonly described as a digital photo or picture frame. This device usually consists of a relatively small LCD screen, typically 5″ to 10″ diagonal, set into a frame suitable for a photo or picture. Digital picture frame devices are typically not mobile devices, but rather are desktop or, in larger sizes, wall-mounted devices. Furthermore, digital picture frame devices are not television devices. The user loads photos into the digital picture frame (i.e. into an internal memory) from a computer, from the memory of a digital camera or from a memory card. The digital picture frame can then display a single photo or perform a slide show of the photos then stored in its internal memory. Alternately, the device can read and display the photos directly from the memory card (without being stored in an internal memory). Some digital picture frames can also display video, such as a camera video. A digital picture frame thus provides greater flexibility in the content that it displays compared to a traditional non-electronic desk or wall mounted picture frame.

Recently, larger wall mounted digital picture frames have been developed, with diagonal screen sizes exceeding 20 inches, with larger and better quality wood and matting frames around the LCD screen. For example, PhotoVu, LLC of Boulder, Colo., markets several different digital photo frame products, some of which include wireless conductivity and a USB port for receiving picture files. The PhotoVu devices do not have remote control and therefore incorporate control buttons on the device. Both the control buttons and the USB port must be readily accessible and thus are not completely hidden from view. Thus, these digital picture frame devices do not have a true picture frame look from all viewing angles. Furthermore these devices run directly on 120 V and thus use the typical 120 V power cords, which are therefore quite difficult to conceal, thereby again detracting from the true picture frame quality look. Although it is possible to conceal the power cord in the wall, this requires locating a 120 V electrical outlet in the wall directly behind the device. Because of safety and building code issues, this task generally requires an electrician.

The PhotoVu digital picture frames also do not include speakers, do not display video, and do not provide a convenient user friendly way of controlling the display of photos and video, thereby greatly limiting both applicability and usability.

There is a need for a wall mounted digital picture frame that truly looks like a non-electronic picture frame from all viewing angles, while providing superior picture and video quality with audio. In addition, this device should provide user friendly control of the photo and video content.

### SUMMARY OF THE INVENTION

The aforementioned problems are solved by providing a digital picture frame device and system that conceals input devices, organizes and displays digital content in the form of playlists, and provides the ability to display different types of digital content.

A digital picture frame device for displaying digital content includes a display screen, a frame surrounding a periphery of the display screen wherein the frame comprises a front surface that provides a visual border around the periphery of the display screen, side surfaces at a periphery of the front surface, and a generally planar back surface opposite the front surface, a compartment accessible by an opening in one of the side surfaces, a movable door for selectively covering the opening in a closed position and providing access to the compartment in an open position, a memory device port disposed in the compartment for receiving a memory device containing digital content, and control circuitry for controlling a display of the digital content on the display screen.

A digital picture frame system includes a computer and a digital picture frame device. The computer includes a processor, a computer-readable medium having computer-executable instructions thereon for a method of generating or receiving digital content and associating at least some of the digital content with one or more playlists. A communications link transfers the one or more playlists of the digital content from the computer to the picture frame device. The picture frame device includes a display screen, a frame surrounding a periphery of the display screen wherein the frame provides a visual border around the periphery of the display screen, and control circuitry for controlling a display of the one or more playlists of the digital content on the display screen.

A digital picture frame device for displaying digital content includes a display screen, a frame surrounding a periphery of the display screen, wherein the frame provides a visual border around the periphery of the display screen, an input device for receiving first digital content in the form of still picture data and second digital content in form of video data, a memory for storing the first digital content received by the input device, and control circuitry for controlling a display on the display screen of the first digital content from the memory, and a display on the display screen of the second digital content from the input device.

Other objects and features of the present invention will become apparent by a review of the specification, claims and appended figures.

### BRIEF DESCRIPTION OF THE DRAWINGS

FIG. 1 is a block diagram of the digital picture frame system which includes a digital picture frame device, a computer, and a communications link.

FIG. 2 is a front view of the digital picture frame device and an optional remote control device.

FIG. 3 is a schematic diagram of the digital picture frame device.

FIG. 4 is a partially exploded perspective view of the digital picture frame device, illustrating a USB port in its folded position.

FIG. 5 is a partially exploded perspective view of the digital picture frame device, illustrating a USB port in its unfolded position.

FIGS. 6A-C are side views of different configurations of the prism waveguide and infrared detector for the remote control sensor.

FIG. 7 is a screen shot illustrating the display of photos in the library and in the playlist.

FIGS. 8A-8D are screen shots illustrating the characteristics windows used to select settings for the display of the digital content.

FIG. 9 is a screen shot of a time-line used to change the transition timings for the photos.

### DETAILED DESCRIPTION OF THE PREFERRED EMBODIMENTS

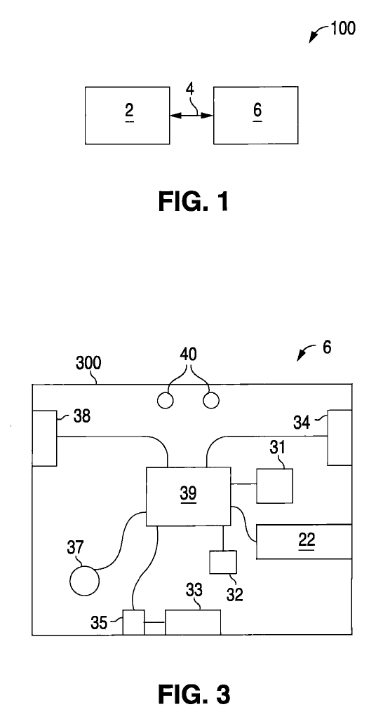

The present invention is a digital picture frame device and system. The system 100 in FIG. 1 comprises a computer 2, a digital picture frame device 6, and a communication link 4 between the computer 2 and the digital picture frame device 6.

Computer 2 can be any well known computing device (e.g. personal computer, server, etc.) that can contain and/or manipulate digital content for display on the digital picture frame device 6. While digital content is shown and described below as still images for brevity, digital content may be any visual image that can be displayed on the digital picture frame device 6, including but not limited to photographs, video, text, graphics and combinations of these forms of content. For purposes of system or device efficiency and for optimal display on device 6, it is preferable that the computer 2 and/or the device 6 convert image files, which can be in a variety of formats, such as TIFF, BMP, GIF, PNG and JPEG to a single image format such as JPEG. Similarly, video files which also can be in a variety of formats, such as WMV, MPEG2, MOV, AVI and MPEG4, preferably are converted to a single video format such as MPEG4. Thus, the display drivers for digital picture frame device 6 need only display these two types of file formats. The digital content can further include audio files for playing music or other sounds in conjunction with the display of the visual images. Preferably, input file conversions and organizing and managing the various display files into playlists is done using a software program resident in computer 2.

Communication link 4 is used for transmitting digital content from the computer 2 to the digital picture frame device 6. In one embodiment, communication link 4 is a memory device, such as a flash memory drive or card, or a removable hard drive, that can be physically transferred between a port on the computer 2 and a port on the digital picture frame device 6. USB memory devices and ports are an example ideal for the present invention. In another embodiment, communication link 4 is a wireless connection (RF, infrared, etc.) between a transmitter or transceiver contained in computer 2 and a receiver or transceiver contained in digital picture frame device 6. In another embodiment, communication link 4 may be a data transmission wire such as an Ethernet cable. Multiple sub-connections may also make up the connection, such as where the communication link 4 comprises a string of routers, as in the Internet or a local access network.

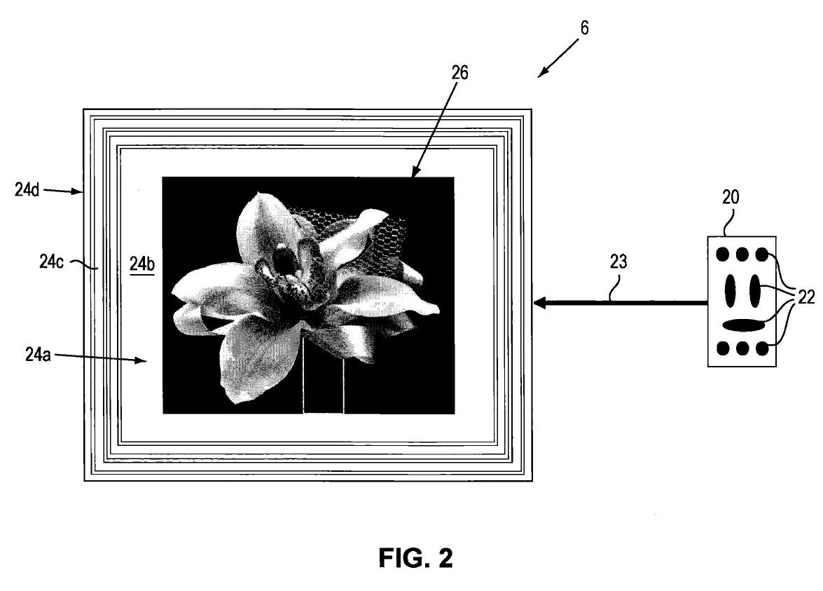

FIG. 2 illustrates a front view of digital picture frame device 6 in more detail. The digital picture frame device 6 includes a visual frame border 24 surrounding the perimeter of a display screen 26. The frame border 24 may be an elaborate border of virtually any material, or combination of materials (i.e. wood frame with matting), to enhance the aesthetic appearance of the device. Alternatively, it may be a simpler wooden or plastic frame that provides a visual border and mechanical support structure for the display screen 26. The display screen 26 is preferably thin, but may be any appropriate electronic visual display screen such as an LCD, a plasma display, or a thin-profile CRT. Preferably, the digital picture frame device 6 has the appearance of a true non-electronic picture frame when it is mounted on a wall.

Typically, high-resolution LCD screens, commonly referred to as TN mode screens, are made for computer monitors. Although TN mode screens can have reasonably wide horizontal viewing angles, they usually have less-wide vertical viewing angles. Thus, TN mode screens are configured such that the center of the window for optimal viewing (in the vertical direction) is offset toward the top of the screen. Said another way, the window for optimal viewing is offset toward the top edge of the screen and thus toward the top edge of the image produced on the screen. This can present an issue for a digital picture frame device 6 hanging on a wall, since the viewer's line of sight often will be from beneath (i.e. when the viewer is seated). Therefore, display screen 26 can be a wide angle LCD screen, commonly called a VA mode screen, which has a wide vertical viewing angle. However, VA mode screens are generally more costly than TN mode screens. Therefore, if TN mode screens are desired to reduce cost, an alternate solution is to rotate the TN mode screen 180° from its conventional orientation so that the window for optimal viewing is offset toward the bottom edge of the screen and thus toward the bottom edge of the image being produced by the screen, to provide better viewing for lines of sight below the digital picture frame device 6. In this configuration, the digital content presented to the screen must also be rotated by 180°, either using software, firmware and/or hardware in computer 2 and/or device 6.

Preferably, the digital picture frame device 6 includes a wireless remote control module 20 with control inputs 22 for sending commands to the digital picture frame device 6 via an infrared or RF communications link 23. Settings such as video and audio controls, display settings, power saving options, play sequence initiation and connections to the host computer may be set using control inputs 22. Alternatively, the control inputs 22 may be positioned on the digital picture frame device 6 itself. In one embodiment, to maintain a true picture frame look, the display screen 26 is a touch sensitive device where control inputs 22 for the digital picture frame device 6 or the system 100 constitute softkeys or menus on the touch screen display 26 itself rather than on a remote control module. In another embodiment, command control is performed from computer 2 via communications link 4 between computer 2 and device 6. In a further embodiment the digital picture frame system may include both communications link 4 (e.g. in the form of a wireless connection between computer 2 and device 6) and a remote control module 20. In such a case, control of the device 6 can be implemented using computer 2 and/or remote control module 20.

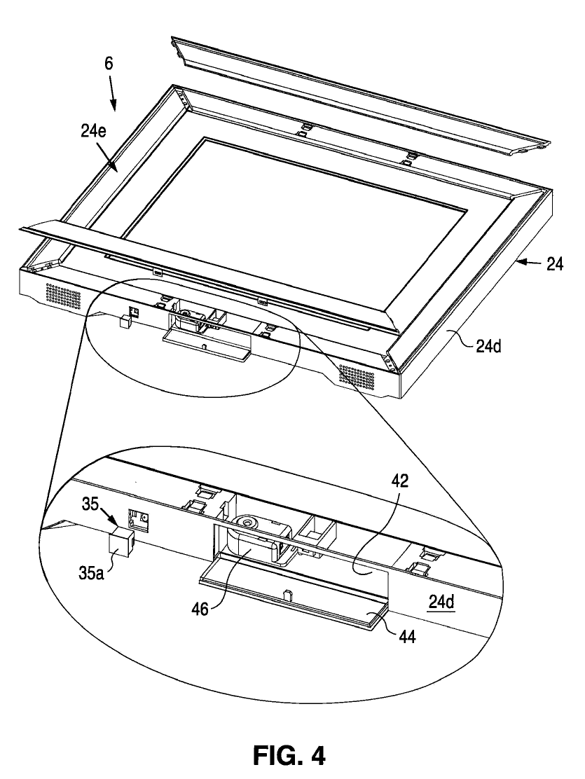

FIG. 3 illustrates a schematic of the digital picture frame device 6. The digital picture frame device 6 contains control circuitry 39 for controlling the various parts of the device. For embodiments that include the remote control 20, an infrared or RF receiver 35 is included, where the control circuitry 39 controls the various parts of the device in response to or in conjunction with signals received from remote control 20 via receiver 35. As such, control circuitry 39 is preferably electrically connected directly or indirectly to most if not all of the electronic components which require control. The digital picture frame device 6 also includes memory 31 for storing any software drivers usable for displaying the content on display screen 26, and may also be used to store the digital content. A housing 300 is used for enclosing and protecting the internal parts of the frame device 6. The housing 300 may contain mounts 40 for hanging the device on a wall, or for attaching a stand for tabletop placement.

The digital picture frame device 6 contains an input 34 for receiving digital content. The input 34 may be a memory card port such as a USB port, a wireless receiver or transceiver, a port for a removable cable, and/or any other input capable of receiving digital content. A power input 33 receives power via a cord from an electrical outlet.

Input 34 could have one or more input device portions for serially or simultaneously receiving different kinds of digital content. For example, input 34 could include a first input portion (e.g. a memory card port) for receiving (and possibly storing in memory 31) digital content in the form of still pictures, photos, and/or video, and a second input portion (e.g. a wireless receiver or transceiver) for receiving digital content in the form of streaming video. In this example, device 6 can display the stored pictures, photos or video, as well as serve as a display for a CCTV system. In another embodiment, a single input portion (e.g. a wireless receiver or transceiver) could receive digital content in the form of pictures, photos or video which are stored in memory 31 for later display, as well as digital content in the form of streaming video for display. In yet another embodiment, input 34 could include a first input portion that is a memory card port (for receiving digital content in the form of pictures, photos or video), and a second input portion that is a plug jack for receiving a wire input plug for a wired communication of the digital content in the form of streaming video.

The power cord can present an aesthetic issue for the wall-mounted device. To minimize the negative visual image of a power cord hanging down from the device, device 6 is driven by low-voltage power and thus a low voltage (typically 12 V) power cord is connected to the device. This low voltage power cord is in turn connected to a power adaptor (e.g. on the floor) that is itself connected to an electrical outlet. The use of a low voltage power cord provides several simple options to conceal the power cord. None of these options require the use of an electrician. Since the power cord is low voltage it can be made as a ribbon cable with a flat profile. The user can then affix the ribbon cable to the wall with a suitably colored or painted-over tape. Alternatively, this low voltage power ribbon cable can be readily concealed in the wall, either by inserting the power ribbon cable edge-wise into a slot in the wall or placing it completely behind the wall through an entrance opening behind the device and an exit opening near the floor to connect to the power adaptor. Since the power ribbon cable is low voltage, there are no safety or building code issues and the user can perform these concealment activities without the aid of an electrician.

The digital picture frame device 6 contains an internal clock 32 that keeps track of time and date. Clock 32 may be any suitable electronic timer device or may be an external clock signal incorporated into control circuitry 39. The clock 32 may be used to modify an active display of the frame device 6 such as slide show speed, to coordinate displayed images with calendar dates, and to synchronize various calendar functions as described in more detail below. Alternately or additionally, the clock 32 may be used to execute timed power on and power off commands.

The digital picture frame device 6 contains an optional sensing device 38 set to respond to certain events. In one embodiment, the sensing device 38 is a motion detector that causes the digital picture frame device 6 to display a repeating sequence of pictures whenever motion is detected. In another embodiment, sensing device 38 is a light detector set to lower the display intensity or turn the power off altogether whenever the level of ambient light in the room drops below a certain threshold. In another embodiment, sensing device 38 is a microphone which causes the digital picture frame device 6 to respond to sound-based commands. Sensing device 38 is optional, and may include any, none, or all of the above within the digital picture frame device 6. One or more speakers 37 may also be included in the digital picture frame device 6 for associating video or pictures with sound or music, or providing verbal information about settings. Alternately or additionally, the sound for speakers 37 can be coupled to external devices and speaker systems in a wired manner or wirelessly (i.e. a transmitter or transceiver associated with the picture frame device 6 sends audio signals to a receiver or transceiver associated with the speakers).

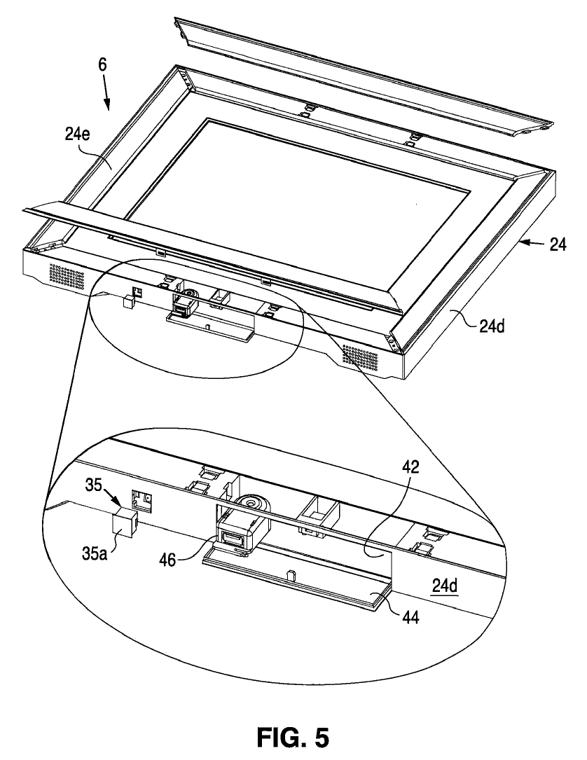

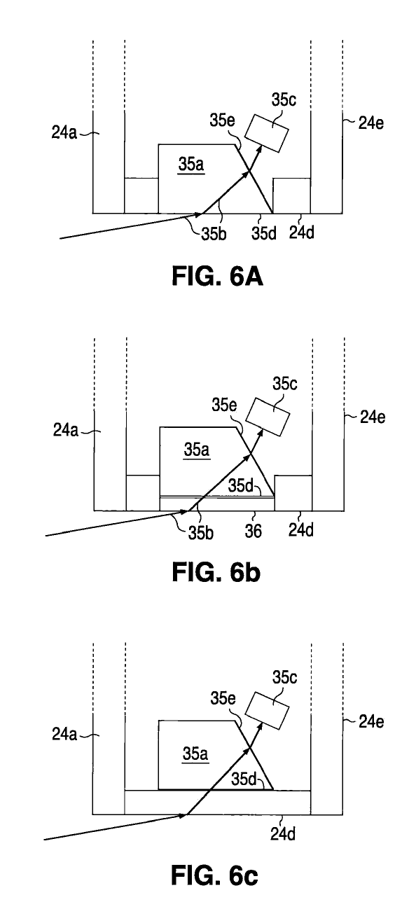

For many applications, it is desired that the outer appearance of the digital picture frame device 6 appear just like a non-electronic picture frame (i.e. where a casual viewer would only see the high-resolution LCD display and the matting/frame of the visual frame border 24, such that the electronic controls and features of the digital picture frame device 6 are not readily noticeable from any viewing angle). The frame 24 preferably has a front surface 24a that includes a matting portion 24b and an outer frame portion 24c that together surround the periphery of the display screen 26 and provide a visual border thereto, a side surface 24d that may or may not be planar at the periphery of the front surface 24a, and a generally planar back surface 24e opposite the front surface 24a that is conducive for mounting against a wall. When the communications link 4 is a removable memory device such as a USB flash drive, providing a memory card port on the visible exterior surfaces of the visual frame border 24 is convenient for the user to load and view digital content, but is visually unappealing especially while the flash drive is placed in the port. Therefore, device 6 includes a hidden memory card port compartment 42 accessible via an opening in an exposed side surface 24d of visual frame border 24 as shown in FIGS. 4-5. Compartment 42 is selectively accessible via a finger-activated latch door 44, which provides access to a memory card port 46. The latch door 44 is movably (e.g. rotatably, slidably, removably, etc.) attached to the visual frame border 24 to selectively cover (and hide) compartment 42 in a closed position and to provide access to compartment 42 in an open position. The memory card port 46 is preferably pivotally mounted inside compartment 42 for rotation to an unfolded position where the input end for receiving the USB flash drive is either facing or extends at least partially out of the compartment opening (see FIG. 5), so that the user can easily insert or remove the flash drive into or from port 46. Compartment 42 is preferably large enough so that the flash drive can fit inside the compartment 42 when the port 46 is rotated back into the folded position (see FIG. 4). Compartment 42 is shown on the bottom side surface of visual frame border 24, but can be located on any exterior exposed surface thereof readily accessible by the user. While the memory card port shown in FIGS. 4-5 is a USB device port, any memory card port can be utilized in compartment 42.

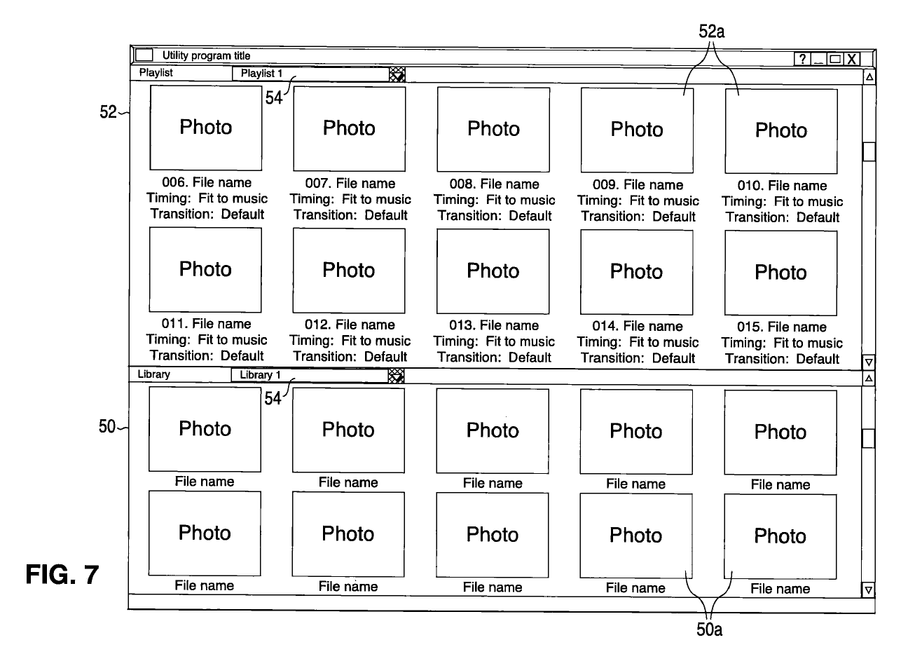

Another feature that can adversely impact the visual appearance of device 6 is the use of an infrared receiver 35 (see FIG. 4) for receiving signals from the remote 20. Infrared sensor receivers typically operate best with a line of sight view to the remote module, and are therefore typically placed on exposed front surfaces of infrared controlled devices, which is not aesthetically pleasing. Device 6 overcomes this problem in one of two ways. In one embodiment, the frame surrounding the display screen is made out of colored polycarbonate or acrylic plastic. These plastics are known to be transparent to the infrared beam from the remote control module, typically with a wavelength at 980 nm, but opaque to visible wavelengths since they are appropriately colored to appear opaque. The infrared sensor 35 is mounted directly behind the front surface of the frame border 24 and thus be in direct line of sight of the remote control module yet not be visible. Alternatively, the infrared sensor 35 can be flush-mounted directly on a side surface 24d of visual frame border 24 (e.g. on the bottom side surface 24d adjacent the compartment 42), as shown in FIGS. 4-5 and 6A. Since such a location is generally not in the direct line of sight view to the remote control module, preferably some form of optical waveguide 35a is used to direct the infrared light 35b to the photodetector 35c, as illustrated in FIG. 6. As a non-limiting example, waveguide 35a can be a prism waveguide made of polycarbonate or acrylic material. The entrance surface 35d of waveguide 35a is flush to the side surface 24d of the frame 24, and preferably colored matched to the color of the side surface. The infrared light from the remote control 20 is incident at an oblique angle to the entrance surface 35d of waveguide 35a, refracted into the prism, and refracted out by the exit surface 35e of the waveguide 35a which had an angular orientation that best directs the light to the infrared detector 35c, as shown in FIG. 6A. Alternately, an infrared transmissive cover plate 36 could be placed over the waveguide entrance surface 35d to better conceal it from view, as shown in FIG. 6B. Or, the waveguide 35a can be placed over the side surface 24d which is made of an infrared transmissive material, as shown in FIG. 6C.

The present invention can include the generation and display of playlists. A playlist is a group of visual images (e.g. photos, videos, etc.) set to display together as a group with specified display characteristics. Playlists can be generated on computer 2 using a software program, running on the computer, where the generated playlists are then downloaded to the digital picture frame device 6 via link 4 for display on the display device 6.

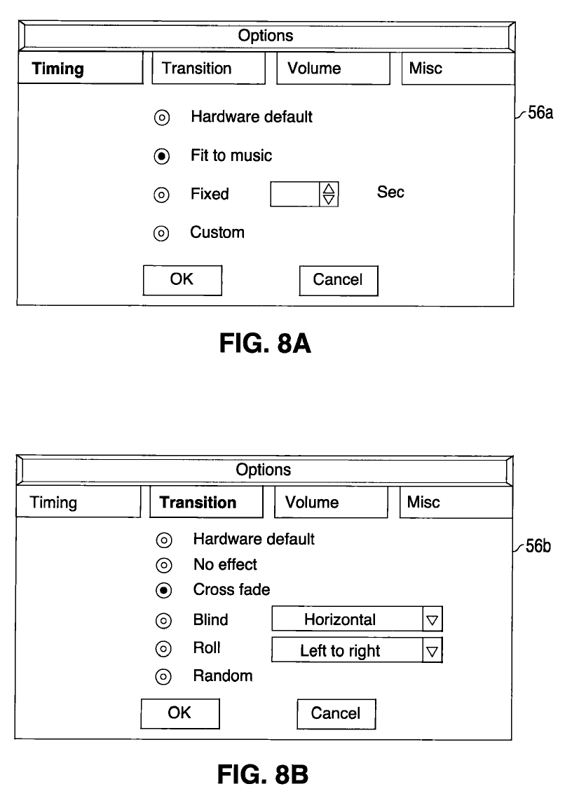

FIG. 7 illustrates the generation of a playlist as viewed on a screen for computer 2. Two windows are displayed: a library window 50 and a playlist window 52. The library window 50 includes a listing or thumbnail pictures 50a of all the photos in a particular library of photos. The playlist window 52 includes a listing or thumbnail pictures 52a of all photos presently included in a playlist. Adding photos 50a from the library 50 to the playlist 52 can be implemented as a drag-and-drop operation from window 50 to window 52. The objects in window 50 can be video and audio files as well. This drag-and-drop operation copies the objects from window 50 to window 52 but leaves the content of window 50 intact. Note, that it is during this drag and drop operation that the software program automatically converts the file format of the image or video selected in window 50 to the appropriate display format preferred by the digital picture frame device, such as JPEG for images, MPEG4 for video and MP3 for audio. The locations of the dropped photos relative to other photos in the playlist can dictate the order in which the photos are displayed, unless a random or other display order is selected. Different playlists and/or libraries can be selected using drop down menus 54. Display characteristics (such as timing, transition, etc. described further below) for photos 52a in the playlist window 52 are listed below each photo 52a. The photos may be manipulated (i.e. centered, cropped, adjusted to remove red-eye, etc.) either before or after being added to the library, or even after being added to any playlists.

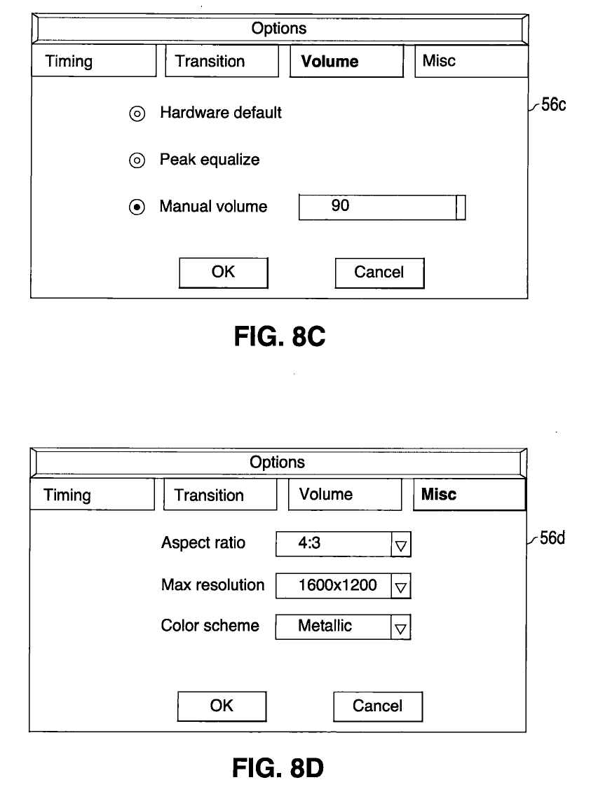

FIGS. 8A-8D illustrates display characteristics windows 56a-56d that allow the user to set display characteristics associated with photos in the playlist or library. Display characteristics can be individually set for each of the photos 52a, or can be globally set for all the photos in a selected playlist or library. The display characteristics windows 56a-56d can be accessed, for example, by a pull down menu, by activating (e.g. selecting, double-clicking, right-clicking, etc.) a selected photo picture 52a in the playlist window 52, or by activating the desired playlist or library generally. The display characteristics windows 56a-56d can be accessed as separate tabs of the same window, separately accessed windows, or a combination of the both.

FIG. 8A illustrates the timing display characteristics window 56a, which controls the timing of the photos being displayed. The user can select between a default setting, a fit-to-music setting (where the photo display timing is synched with audio such as music), a fixed timing setting, and a custom setting (where the user can customize the timing of each photo display). FIG. 8B illustrates the transition display characteristics window 56b, which allows the user to select the appearance of the transition from one photo to the next. The user can choose to have no transition effect, a default effect, or one of a plurality of pre-selected effects. FIG. 8C illustrates the volume display characteristics window 56c, which allows the user to select the volume amplitude and/or equalization effects (e.g. match volume with other playlists or implement a constant sound volume) while the photos are being displayed. Activation of this setting maintains a constant volume so that the user need not adjust volume control while displaying different playlists. FIG. 8D illustrates the miscellaneous display characteristics window 56d, which allows the user to set miscellaneous display characteristics such as aspect ratio, resolution and color scheme.

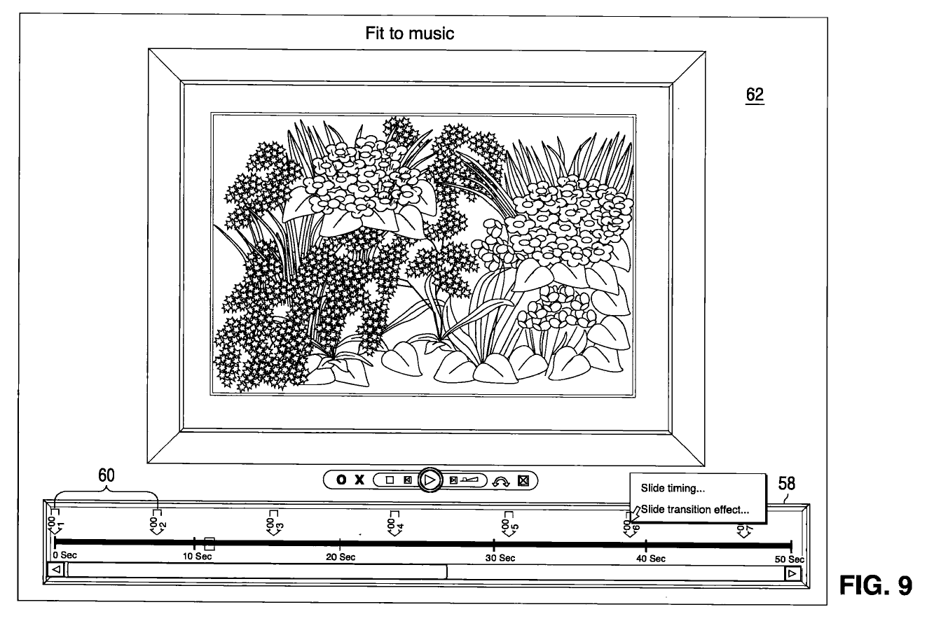

The fit-to-music feature can be implemented in several ways. The simplest implementation is to evenly divide the number of photos in the selected playlist by the total length of the selected audio (e.g. which can be a single or multiple pieces of music, etc.), so that each photo in the playlist is displayed for the same amount of time. Alternately, the computer 2 can provide a fit-to-music utility screen so that the user can customize the actual times each photo is displayed. FIG. 9 illustrates a fit-to-music utility screen 62 that provides a tool bar 58 with movable markers 60 on a time line that dictate when the photo transitions occur. The user can slide the markers 60 to change the timing of the transitions between photos. Fit-to-music can also be implemented by sensing tempo, volume, or other changes in the music and timing the photo transitions accordingly.

Display 6 can include an internal clock, where, in conjunction with setting selections made in the software program, the display of the playlist(s) are triggered by time and/or date information in the clock. Different playlists can be triggered for display based upon the various events such as birthdays, anniversaries, and/or by the time of day, day of the week, etc. For example, device 6 can display a playlist of birthday pictures coupled with birthday music on a birthday event.

It is to be understood that the present invention is not limited to the embodiment(s) described above and illustrated herein, but encompasses any and all variations falling within the scope of the appended claims. For example, for certain applications, computer 2 can be omitted, where the digital content is loaded or supplied to the digital picture frame device 6 directly from a camera or memory card. While the embodiments have been described mainly with respect to photos and music, the device 6 can be utilized to display any visual content and in conjunction with any audio content.

What is claimed is:

1. A digital picture frame device for displaying digital content, comprising:
a display screen;
a frame surrounding a periphery of the display screen, wherein the frame comprises a front surface that provides a visual border around the periphery of the display screen, side surfaces at a periphery of the front surface, and a generally planar back surface opposite the front surface;
a compartment accessible by an opening in one of the side surfaces;
a movable door for selectively covering the opening in a closed position and providing access to the compartment in an open position;
a memory device port disposed in the compartment for receiving a memory device containing digital content; and
control circuitry for controlling a display of the digital content on the display screen.

2. The device of claim 1 wherein the frame front surface comprises a matting portion surrounding the periphery of the display screen, and an outer frame portion surrounding a periphery of the matting portion.

3. The device of claim 1, wherein the memory device port is rotatably disposed in the compartment between an unfolded position in which an input end of the memory device port faces or extends at least partially out of the opening, and a folded position in which the memory device port is contained completely inside the compartment and the input end is not facing the opening.

4. The device of claim 3 wherein the memory device port is a USB port.

5. The device of claim 1, further comprising:
an infrared sensor for receiving infrared signals mounted inside the frame, wherein the control circuitry is configured to control the display of the digital content on the display screen in response to the infrared signals received by the infrared sensor; and
an optical waveguide having an outer surface disposed flush with one of the side surfaces for directing infrared signals to the sensor.

6. The device of claim 1, further comprising:
an infrared sensor for receiving infrared signals mounted inside the frame, wherein the control circuitry is configured to control the display of the digital content on the display screen in response to the infrared signals received by the infrared sensor;
a cover plate having an outer surface disposed flush with one of the side surfaces for capturing infrared signals; and
an optical waveguide for receiving infrared signals from the cover plate and for directing the infrared signals to the sensor.

7. The device of claim 1, wherein the frame is made of a material that is visually opaque yet at least partially transmissive of infrared signals, the device further comprising:
an infrared sensor mounted inside the frame for receiving infrared signals passing through the frame material, wherein the control circuitry is configured to control the display of the digital content on the display screen in response to the infrared signals received by the infrared sensor.

8. The device of claim 1 wherein the display screen is a touch-sensitive display screen for displaying softkeys or menus, and wherein the control circuitry is configured to control the display of the digital content on the display screen in response to activation of the softkeys or menus.

9. The device of claim 1, further comprising:
a wireless receiver or transceiver for receiving wireless signals, wherein the control circuitry is configured to control the display of the digital content on the display screen in response to the wireless signals received by the wireless transceiver.

10. The device of claim 1 further comprising:
one or more speakers, wherein the control circuitry is configured to control the one or more speakers to output an audio portion of the digital content.

11. The device of claim 10, wherein the one or more speakers are disposed inside the frame.

12. The device of claim 10, wherein the one or more speakers are external to the frame.

13. The device of claim 10 further comprising:
a wireless transmitter or transceiver disposed in the frame for transmitting an audio portion of the digital content; and
a wireless receiver or transceiver connected to the one or more speakers for receiving the transmitted audio portion of the digital content.

14. The device of claim 1, wherein the display screen has a window of optimal viewing that is offset toward a bottom edge of the display screen; and wherein the control circuitry configures images of the digital content such that bottom edges of the images are displayed along the bottom edge of the display screen.

15. A digital picture frame system comprising:
a computer that comprises:
a processor,
a computer-readable medium having computer-executable instructions thereon for a method of generating or receiving digital content and associating at least some of the digital content with one or more playlists;
a communications link for transferring the one or more playlists of the digital content from the computer to a picture frame device, wherein the picture frame device comprises:
a display screen,
a frame surrounding a periphery of the display screen, wherein the frame provides a visual border around the periphery of the display screen, and
control circuitry for controlling a display of the one or more playlists of the digital content on the display screen.

16. The system of claim 15 wherein the computer-readable medium further comprising computer-executable instructions thereon for converting the digital content from one type of format to another type of format.

17. The system of claim 15 wherein the one or more playlists includes display characteristics associated therewith, and wherein the control circuitry is configured to display the one or more playlists of the digital content in a manner specified by the display characteristics.

18. The system of claim 17, wherein the digital content includes a plurality of image slides, and wherein the display characteristics includes at least one of a display time for each of the image slides and a transition effect for transitioning between the image slides.

19. The system of claim 17 wherein the computer-readable medium further comprising computer-executable instructions thereon for adjusting the display characteristics based upon a user input.

20. The system of claim 15, wherein the digital content includes audio and a plurality of image slides, and wherein control electronics are configured to transition between the display of the image slides based upon an attribute of the audio.

21. The system of claim 20, wherein the attribute is a length of the audio.

22. The system of claim 20, wherein the audio includes music, and where the attribute is changes in at least one of a tempo and a volume of the music.

23. The system of claim 15, wherein the control circuitry further comprises a clock for keeping date and time, and wherein the control circuitry modifies the display of the digital content on the display screen in response to the clock.

24. The system of claim 15, wherein the picture frame device further comprises:
an internal memory for storing the digital content.

25. The system of claim 15, wherein the communications link comprises:
a first memory device port connected to the computer;
a second memory device port connected to the picture frame device; and
a memory device connectable to the first and second memory device ports.

26. The system of claim 15, wherein the communications link comprises:
a transmitter or first transceiver connected to the computer for transmitting the one or more playlists of the digital content from the computer; and
a receiver or second transceiver connected to the picture frame device for receiving the transmitted one or more playlists of the digital content.

27. The system of claim 15, wherein:
the one or more playlists of digital content includes audio;
the picture frame device includes one or more speakers for outputting the audio; and
the computer-readable medium further comprising computer-executable instructions thereon for equalizing a volume of the audio.

28. The system of claim 15, wherein:
the one or more playlists of digital content includes audio;
the picture frame device includes one or more speakers for outputting the audio; and
the control circuitry is configured to equalize a volume of the audio.

29. The system of claim 15, wherein:
the display screen has a window of optimal viewing that is offset toward a bottom edge of the display screen; and
the computer is further configured to orient images of the digital content such that bottom edges of the images are displayed along the bottom edge of the display screen.

30. A digital picture frame device for displaying digital content, comprising:
a display screen;
a frame surrounding a periphery of the display screen, wherein the frame provides a visual border around the periphery of the display screen;
an input device for receiving first digital content in the form of still picture data and second digital content in form of video data;
a memory for storing the first digital content received by the input device; and
control circuitry for controlling a display on the display screen of the first digital content from the memory, and a display on the display screen of the second digital content from the input device.

31. The device of claim 30, wherein the frame comprises a matting portion surrounding the periphery of the display screen, and an outer frame portion surrounding a periphery of the matting portion.
